(19) United States
(12) Patent Application Publication
(10) Pub. No.: US 2025/0293067 A1
(43) Pub. Date: Sep. 18, 2025

(54) WAFER CARRYING DEVICE

(71) Applicant: Powerchip Semiconductor Manufacturing Corporation, Hsinchu (TW)

(72) Inventor: Huang-Wen Chen, Hsinchu City (TW)

(73) Assignee: Powerchip Semiconductor Manufacturing Corporation, Hsinchu (TW)

(21) Appl. No.: 18/650,106

(22) Filed: Apr. 30, 2024

(30) Foreign Application Priority Data
Mar. 13, 2024 (TW) 113109085

(51) Int. Cl. H01L 21/677; A47B 55/00

(52) U.S. Cl. CPC H01L 21/6773; A47B 55/00

(57) ABSTRACT

A wafer carrying device, adapted to accommodate a first wafer and a second wafer, includes a top portion, a bottom portion, a plurality of supporting components, and a plurality of solid partition plates. The bottom portion is opposite to the top portion. The plurality of supporting components connects the top portion and the bottom portion near edges thereof. The plurality of solid partition plates are located between the top portion and the bottom portion, separate from each other, fixed on the plurality of supporting components, and defines a plurality of slots. A first wafer and a second wafer are adapted to be disposed in two adjacent slots of the plurality of slots and are separated by one of the plurality of solid partition plates.

### CROSS-REFERENCE TO RELATED APPLICATION

This application claims the priority benefit of Taiwan application serial no. 113109085, filed on Mar. 13, 2024. The entirety of the above-mentioned patent application is hereby incorporated by reference herein and made a part of this specification.

### BACKGROUND

### Technical Field

The disclosure relates to a carrying device, and particularly relates to a wafer carrying device.

### Description of Related Art

In a manufacturing process for semiconductor, a wafer carrying device such as a wafer boat can accommodate product wafers and may be further disposed in the furnace tube, so as to heat the product wafers to the required reaction temperature. Non-product wafers, such as monitor wafers used to monitor film formation, may also be placed in the wafer carrying device. In general, the films (made of silicon dioxide and silicon nitride, for example) formed on the surface of a non-product wafer may be removed through a cleaning process, so that the non-product wafer may be recycled and reused. However, the cleaning process cannot completely remove all the contaminants formed on the non-product wafer. In the next manufacturing process, these contaminants on the reused non-product wafer will diffuse to the surface of the product wafer after being heated, resulting in poor electrical properties and yield of the product.

### SUMMARY

The disclosure provides a wafer carrying device, which effectively prevents a wafer from being contaminated.

A wafer carrying device, adapted to accommodate a first wafer and a second wafer, includes a top portion, a bottom portion, a plurality of supporting components, and a plurality of solid partition plates. The bottom portion is opposite to the top portion. The plurality of supporting components connects the top portion and the bottom portion near edges of the top portion and the bottom portion. The plurality of solid partition plates are located between the top portion and the bottom portion, separate from each other, fixed on the plurality of supporting components, and defines a plurality of slots. The first wafer and the second wafer are adapted to be disposed in two adjacent slots of the plurality of slots and are separated by one of the plurality of solid partition plates.

In an embodiment of the disclosure, the plurality of solid partition plates are disposed at equal intervals between the top portion and the bottom portion along a central axis of the top portion.

In an embodiment of the disclosure, the top portion, the bottom portion, and the plurality of supporting components form an accommodation space. The accommodation space includes an upper space adjacent to the top portion, a middle space, and a lower space adjacent to the bottom portion. The middle space is located between the upper space and the lower space. The plurality of solid partition plates are disposed only in the upper space, in the lower space, or in both the upper space and the upper space, along the central axis of the top portion.

In an embodiment of the disclosure, the middle space is a through space. The middle space is larger than the upper space, and the middle space is larger than the lower space.

In an embodiment of the disclosure, each of the plurality of supporting components includes a plurality of carrying portions stacked in a direction from the top portion to the bottom portion. Each of the plurality of carrying portions includes a carrying surface. The first wafer or the second wafer is adapted to be supported by the carrying surface.

In an embodiment of the disclosure, the plurality of solid partition plates and the plurality of carrying portions are arranged alternately in the direction from the top portion to the bottom portion.

In an embodiment of the disclosure, each of the plurality of solid partition plates is located between two adjacent carrying portions of the plurality of carrying portions.

In an embodiment of the disclosure, each of the plurality of supporting components includes a main portion and a plurality of carrying portions. The main portion connects the top portion and the bottom portion. The plurality of carrying portions are spaced apart, disposed on the main portion, and extend horizontally towards the central axis of the top portion. Each of the plurality of carrying portions includes a carrying surface. The first wafer or the second wafer is adapted to be supported by the carrying surface.

In an embodiment of the disclosure, each of the plurality of solid partition plates is located between two adjacent carrying portions of the plurality of carrying portions.

In an embodiment of the disclosure, a projection of each of the plurality of solid partition plates on a plane where the top portion is located is overlapped with the top portion, or/and the projection of each of the plurality of solid partition plates on a plane where the bottom portion is located is overlapped with the bottom portion.

Based on the above, in the wafer carrying device of the disclosure, the plurality of solid partition plates are separate from each other, and the plurality of slots are defined between the top portion and the bottom portion. The first wafer and the second wafer are adapted to be disposed in two adjacent slots of the plurality of slots and separated by one of the plurality of solid partition plates. In this way, contaminants from the second wafer are effectively blocked by the solid partition plate and is unable to diffuse to the first wafer, thereby enhancing the electrical properties and yield of the product made from the first wafer.

### BRIEF DESCRIPTION OF THE DRAWINGS

FIG. 1 is a schematic diagram of a wafer carrying device according to an embodiment of the disclosure.

FIG. 2 is a partial front view of the wafer carrying device of FIG. 1 carrying a first wafer and a second wafer.

FIG. 3 is a partial schematic diagram of FIG. 2 from another angle of view.

FIG. 4 is a schematic diagram of a wafer carrying device according to another embodiment of the disclosure.

FIG. 5 is a schematic diagram of a wafer carrying device according to another embodiment of the disclosure.

FIG. 6 is a partial front view of the wafer carrying device of FIG. 5 carrying a first wafer and a second wafer.

### DESCRIPTION OF THE EMBODIMENTS

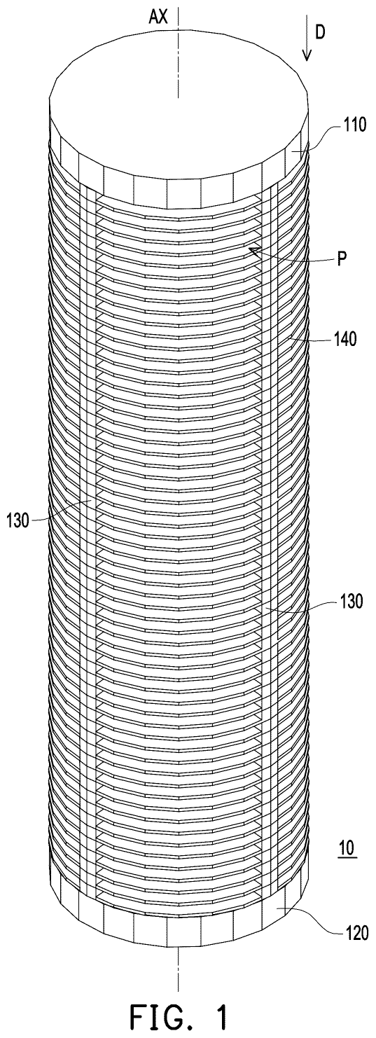

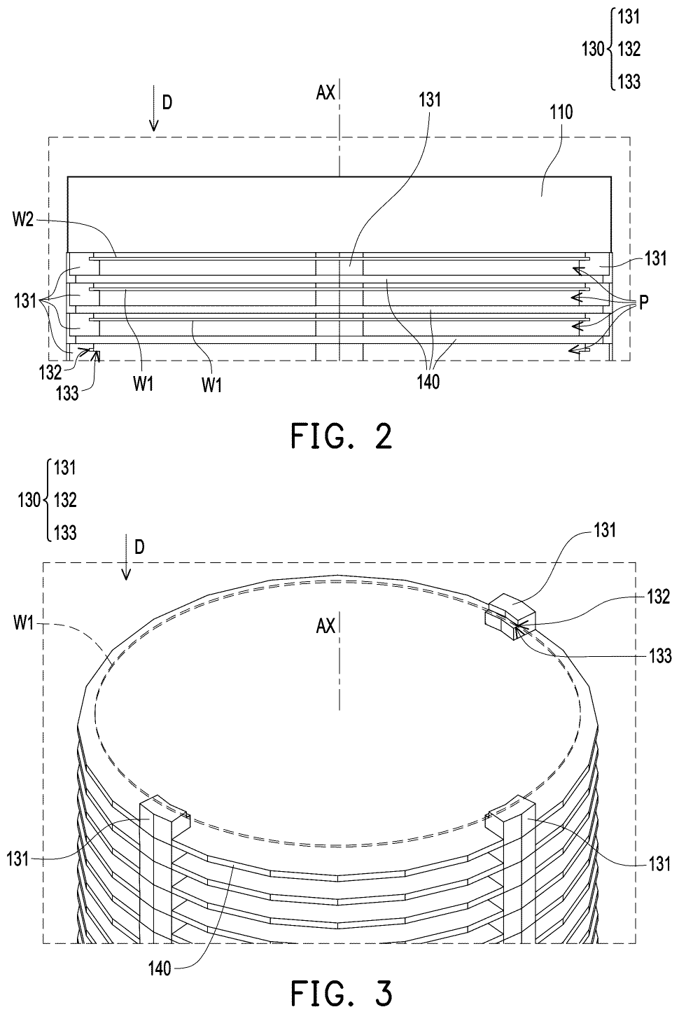

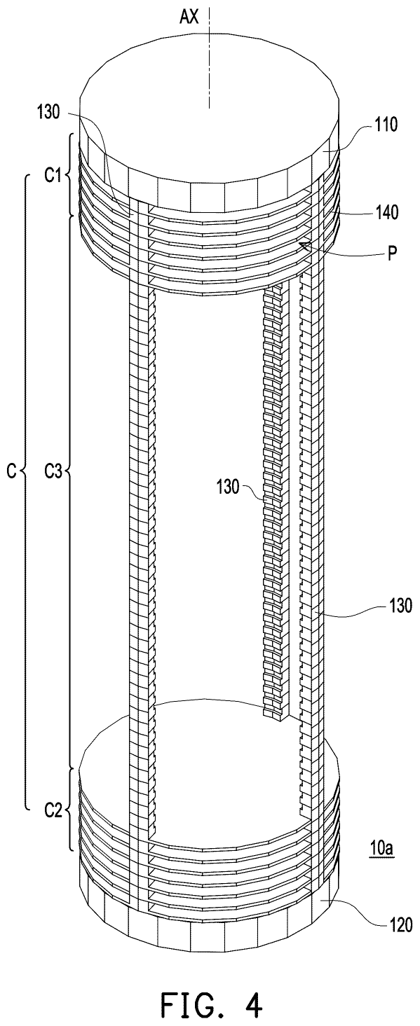

FIG. 1 is a schematic diagram of a wafer carrying device according to an embodiment of the disclosure. FIG. 2 is a partial front view of the wafer carrying device of FIG. 1 carrying a first wafer and a second wafer. FIG. 3 is a partial schematic diagram of FIG. 2 from another angle of view. To clearly present the supporting components, the top portion of the wafer carrying device is hidden and the first wafer is drawn with dotted lines in FIG. 3.

Referring to FIG. 1 to FIG. 3, in this embodiment, a wafer carrying device 10 is, for example, a wafer boat, which is adapted to accommodate a first wafer W1 (FIG. 2), so as to apply a manufacturing process (for example, a process of heating by furnace tube) for semiconductor to a batch of the first wafers W1. The wafer carrying device 10 may also accommodate a second wafer W2 (FIG. 2). The second wafer W2 is, for example, a monitor wafer, which may be used to monitor the status of film formation on the first wafer W1 and may be recycled and reused through a cleaning process after the manufacturing process is completed, but the type of the second wafer W2 is not limited thereto.

In the embodiment, the wafer carrying device 10 includes a top portion 110, a bottom portion 120 opposite to the top portion 110, a plurality of supporting components 130, and a plurality of solid partition plates 140. The top portion 110 and the bottom portion 120 are parallel to each other. The plurality of supporting components 130 connects the top portion 110 and the bottom portion 120 near the edges of the top portion 110 and the bottom portion 120. The plurality of solid partition plates 140 are located between the top portion 110 and the bottom portion 120, separate from each other, fixed to the supporting components 130, and defines a plurality of slots P between the top portion 110 and the bottom portion 120.

Specifically, as illustrated in FIG. 2 and FIG. 3, each of the plurality of supporting components 130 includes carrying portions 131 stacked in a direction D from the top portion 110 to the bottom portion 120 (FIG. 1). Each of the plurality of carrying portions 131 includes a recess 132 located on the inside to form a carrying surface 133. The recess 132 and the carrying surface 133 are parallel to the top portion 110.

In the embodiment, the first wafer W1 and the second wafer W2 are adapted to be disposed in two adjacent slots P of the plurality of slots P and are separated by one of the plurality of solid partition plates 140. Specifically, the first wafer W1 and the second wafer W2 are adapted to be inserted into the recess 132 and supported by the carrying surface 133. In other words, the first wafer W1 or the second wafer W2 may be inserted into the recess 132, at the same height, of each of the supporting components 130, and may be supported by the carrying portions 131 at the same height. In another embodiment, the plurality of carrying portions 131 do not include the recess 132, and the first wafer W1 or the second wafer W2 is supported by the carrying surface 133, which still allows proper placement of the first wafer W1 or the second wafer W2.

In this embodiment, for example, the plurality of supporting components 130 include three supporting components 130. Therefore, the first wafer W1 or the second wafer W2 may be inserted into three recesses 132 located at the same height and simultaneously supported by the three carrying portions 131 located at the same height. However, the number of the supporting components 130 is not limited thereto.

As depicted in FIG. 1, the plurality of solid partition plates 140 in the embodiment are disposed at equal intervals between the top portion 110 and the bottom portion 120 (FIG. 1) along a central axis AX of the top portion 110. In addition, the plurality of solid partition plates 140 and the plurality of carrying portions 131 are arranged alternately in the direction D. That is, each of the plurality of solid partition plates 140 is located between two adjacent carrying portions 131 of the plurality of carrying portions 131.

Generally, after undergoing a process using a furnace tube, a non-product wafer in the wafer carrying device may be recycled and reused. However, since the subsequent cleaning process cannot completely remove all the contaminants on the non-product wafer, these contaminants may easily diffuse to the surface of the product wafer due to the heat in the next manufacturing process, resulting in poor electrical properties and yield of the product.

In contrast, in this embodiment, when the first wafer W1 and the second wafer W2 are disposed in the slots P, the wafer carrying device 10 separates the first wafer W1 and the second wafer adjacent to each other by the solid partition plate 140, reducing the possibility of the contaminants on the second wafer W2 diffusing to the first wafer W1, thereby enhancing the electrical properties and yield of the product.

It is noteworthy that the area enclosed by an edge of the solid partition plate 140 is equal to the area of the solid partition plate 140 itself. In other words, the solid partition plate 140 has no hollow areas, holes, or any recess from the edge, and thus ensures more effective blocking. When the contaminants from the second wafer W2 is heated and diffuse in the furnace tube, the contaminants cannot pass through the solid partition plate 140 in the direction D to arrive at the adjacent first wafer W1, and thus the first wafer W1 is further prevented from being contaminated.

It should also be noted that FIG. 2 and FIG. 3 schematically illustrates the first wafer W1 and/or the second wafer W2, and they are not used to limit the sizes, thicknesses, positions and arrangement of the first wafer W1 and the second wafer W2.

FIG. 4 is a schematic diagram of a wafer carrying device according to another embodiment of the disclosure. A main difference between the embodiment illustrated in FIG. 4 and the embodiment illustrated in FIG. 1 is that the solid partition plates 140 are only disposed in a local space in the wafer carrying device 10a in FIG. 4. Specifically, the top portion 110, the bottom portion 120, and the plurality of supporting components 130 form an accommodation space C. The accommodation space C includes an upper space C1 adjacent to the top portion 110, a middle space C3, and a lower space C2 adjacent to the bottom portion 120. The middle space C3 is located between the upper space C1 and the lower space C2.

In this embodiment, the middle space C3 is a through space. The middle space C3 is larger than the upper space C1, and the middle space C3 is larger than the lower space C2. The solid partition plates 140 are disposed in the upper space C1 and the lower space C2. In another embodiment, the solid partition plates 140 are only disposed in the upper space C1. In another embodiment, the solid partition plates 140 are only disposed in the lower space C2. The first wafer W1 (FIG. 2) is only disposed in the middle space C3.

Since the middle space C3 is not occupied by the solid partition plates 140, and the middle space C3 is larger than each of the upper space C1 and the lower space C2, the middle space C3 may be designed to accommodate more first wafers W1, thereby improving space utilization. In addition, the middle space C3 generally has better uniformity of air flow and thermal stability compared with the upper space C1 and the lower space C2. Therefore, locating the first wafer W1 within the middle space C3 provides excellent film formation.

In addition, the second wafer W2 (FIG. 2) in the embodiment is disposed only in the upper space C1, in the lower space C2, or in both the upper space C1 and the lower space C2. Similar to the embodiment shown in FIG. 2, the first wafer W1 and the second wafer W2 are separated by the solid partition plate 140, which prevents the contaminants on the second wafer W2 from diffusing to the first wafer W1 and causing the first wafer W1 to be contaminated, thereby enhancing the electrical properties and yield of products.

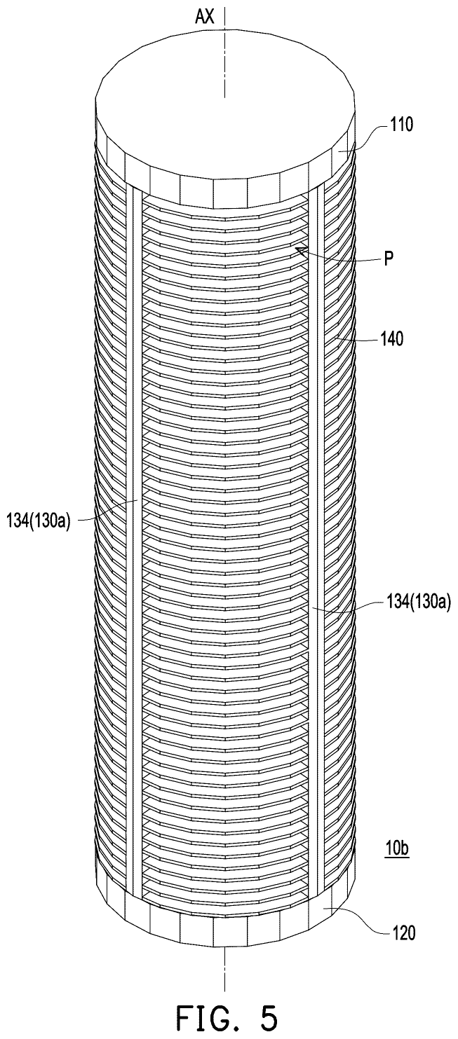

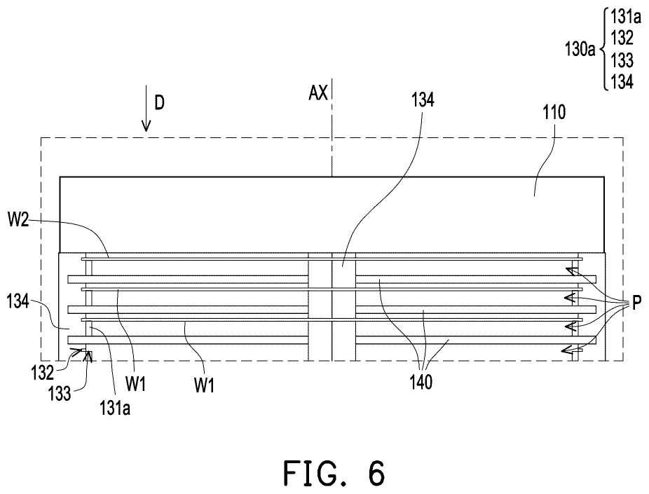

FIG. 5 is a schematic diagram of a wafer carrying device according to another embodiment of the disclosure. FIG. 6 is a partial front view of the wafer carrying device of FIG. 5 carrying a first wafer and a second wafer. A main difference between the embodiment illustrated in FIG. 5 and FIG. 6 and the embodiment illustrated in FIG. 1 is that each of the plurality of supporting components 130a of the wafer carrying device 10b in FIG. 5 and FIG. 6 includes a main portion 134 and a plurality of carrying portions 131a (FIG. 6).

Specifically, the main portion 134 connects the top portion 110 and the bottom portion 120, and the plurality of carrying portions 131a are spaced apart, disposed on the main portion 134 and extend horizontally toward the central axis AX of the top portion 110. In other words, in this embodiment, the main portion 134 is a structure formed in a single piece, rather than the supporting component 130 formed by stacking the plurality of carrying portions 131 in the wafer carrying device 10 shown in FIG. 1.

As depicted in FIG. 6, each of the plurality of carrying portions 131a includes a recess 132 located on the inside to form the carrying surface 133. The first wafer W1 or the second wafer W2 is adapted to be inserted into the recess 132 and is supported by the carrying surface 133. Each of the plurality of solid partition plates 140 is located between two adjacent carrying portions 131a of the plurality of carrying portions 131a. In another embodiment, the plurality of carrying portions 131a do not include the recess 132, and the first wafer W1 or the second wafer W2 is supported by the carrying surface 133, which still allows proper placement of the first wafer W1 or the second wafer W2. The remaining structural features of the wafer carrying device 10b are the same or similar to the wafer carrying device 10a, and will not be repeatedly described here.

It should be noted that FIG. 6 schematically illustrates the first wafer W1 and the second wafer W2, but it is not used to limit the sizes, thicknesses, positions and arrangement of the first wafer W1 and the second wafer W2.

In summary, in the wafer carrying device of the disclosure, the plurality of solid partition plates are separate from each other, and the plurality of slots are defined between the top portion and the bottom portion. The first wafer and the second wafer are adapted to be placed adjacent to each other in the plurality of slots and separated by one of the plurality of solid partition plates. In this way, contaminants from the second wafer are effectively blocked by the solid partition plate and cannot diffuse to the first wafer, thereby enhancing the electrical properties and yield of the product made from the first wafer.

In addition, the solid partition plates may be disposed in only the upper space and the lower space of the accommodation space without occupying the middle space. Therefore, the middle space may be designed to accommodate more first wafers, further improving the space utilization of the wafer carrying device.

1. A wafer carrying device, adapted to accommodate a first wafer and a second wafer, comprising:
a top portion;
a bottom portion, opposite to the top portion;
a plurality of supporting components, connecting the top portion and the bottom portion adjacent to edges of the top portion and the bottom portion; and
a plurality of solid partition plates, located between the top portion and the bottom portion, separate from each other, fixed to the plurality of supporting components, and defining a plurality of slots between the top portion and the bottom portion,
wherein the first wafer and the second wafer are adapted to be disposed in two adjacent slots of the plurality of slots and are separated by one of the plurality of solid partition plates.

2. The wafer carrying device according to claim 1, wherein the plurality of solid partition plates are disposed at equal intervals between the top portion and the bottom portion along a central axis of the top portion.

3. The wafer carrying device according to claim 1, wherein the top portion, the bottom portion, and the plurality of supporting components form an accommodation space, the accommodation space comprises an upper space adjacent to the top portion, a middle space, and a lower space adjacent to the bottom portion, the middle space is located between the upper space and the lower space, and the plurality of solid partition plates are disposed only in the upper space, in the lower space, or in both the upper space and the upper space, along a central axis of the top portion.

4. The wafer carrying device according to claim 3, wherein the middle space is a through space, the middle space is larger than the upper space, and the middle space is larger than the lower space.

5. The wafer carrying device according to claim 1, wherein each of the plurality of supporting components comprises a plurality of carrying portions stacked in a direction from the top portion to the bottom portion, each of the plurality of carrying portions comprises a carrying surface, and the first wafer or the second wafer is adapted to be supported by the carrying surface.

6. The wafer carrying device according to claim 5, wherein the plurality of solid partition plates and the plurality of carrying portions are arranged alternately in the direction from the top portion to the bottom portion.

7. The wafer carrying device according to claim 5, wherein each of the plurality of solid partition plates is located between two adjacent carrying portions of the plurality of carrying portions.

8. The wafer carrying device according to claim 1, each of the plurality of supporting components comprises a main portion and a plurality of carrying portions, the main portion connects the top portion and the bottom portion, and the plurality of carrying portions are spaced apart, disposed on the main portion, and extend horizontally towards a central axis of the top portion, each of the plurality of carrying portions comprises a carrying surface, the first wafer or the second wafer is adapted to be supported by the carrying surface.

9. The wafer carrying device according to claim 8, wherein each of the plurality of solid partition plates is located between two adjacent carrying portions of the plurality of carrying portions.

10. The wafer carrying device according to claim 1, wherein an area enclosed by an edge of each of the plurality of solid partition plates is equal to an area of each of the plurality of solid partition plates.
